(19) United States
(12) Patent Application Publication
(10) Pub. No.: US 2026/0033137 A1
(43) Pub. Date: Jan. 29, 2026

(54) Electronic Device with an Under-Display Sensor and Shorted Subpixels

(71) Applicant: Apple Inc., Cupertino, CA (US)

(72) Inventors: Shyuan Yang, San Jose, CA (US); Abbas Jamshidi Roudbari, Saratoga, CA (US); Chin-Wei Lin, San Jose, CA (US); Fan Gui, Sunnyvale, CA (US); Jean-Pierre S Guillou, La Jolla, CA (US); John S Zhang, San Jose, CA (US); Ran Tu, Palo Alto, CA (US); Shiyi Liu, San Jose, CA (US); Tae-Wook Koh, San Jose, CA (US); Ting-Kuo Chang, San Jose, CA (US); Tsung-Ting Tsai, San Jose, CA (US); Warren S Rieutort-Louis, Cupertino, CA (US); Yi Qiao, San Jose, CA (US); Yuchi Che, Santa Clara, CA (US); Zhizhen Ma, San Jose, CA (US)

(21) Appl. No.: 19/239,447

(22) Filed: Jun. 16, 2025

Related U.S. Application Data
(60) Provisional application No. 63/676,250, filed on Jul. 26, 2024.

(51) Int. Cl. H10K 59/121; H10K 59/35; H10K 59/60

(52) U.S. Cl. CPC H10K 59/1213; H10K 59/352; H10K 59/353; H10K 59/60

(57) ABSTRACT

A display may overlap a sensor such as a camera or ambient light sensor. A portion of the display that overlaps the sensor may be modified to increase transparency relative to the remaining portion of the display. The modified portion of the display may have emissive subpixels that are shorted together. The emissive subpixels that are shorted together may have different sizes. A larger emissive subpixel may overlap the thin-film transistor subpixels whereas a smaller emissive subpixel may not overlap any of the thin-film transistor subpixels. To increase the size of transparent windows through the display, emissive subpixels may be shifted relative to a layout used in the remaining portion of the display.

This application claims the benefit of U.S. provisional patent application No. 63/676,250, filed Jul. 26, 2024, which is hereby incorporated by reference herein in its entirety.

### BACKGROUND

This relates generally to electronic devices, and, more particularly, to electronic devices with displays.

Electronic devices often include displays. For example, an electronic device may have a light-emitting diode (LED) display based on light-emitting diode pixels. In this type of display, each pixel includes a light-emitting diode and circuitry for controlling application of a signal to the light-emitting diode to produce light.

There is a trend towards borderless electronic devices with a full-face display. These devices, however, may still need to include sensors such as cameras, ambient light sensors, and proximity sensors to provide other device capabilities. Since the display now covers the entire front face of the electronic device, the sensors will have to be placed under the display stack.

It is within this context that the embodiments herein arise.

### SUMMARY

An electronic device may include an input-output component and a display having a plurality of subpixels. The plurality of subpixels may include emissive subpixels that emit light and thin-film transistor subpixels that control the emissive subpixels. The display may include a first portion with a first number of emissive subpixels per unit area and a second number of thin-film transistor subpixels per unit area and a second portion with a third number of emissive subpixels per unit area that is equal to the first number and a fourth number of thin-film transistor subpixels per unit area that is less than the second number. In the first portion, each emissive subpixel of a first color may have a first area, the second portion may overlap the input-output component, and in the second portion a first subset of emissive subpixels of the first color each may have a second area that is larger than the first area and a second subset of emissive subpixels of the first color each may have a third area that is smaller than the first area.

An electronic device may include an input-output component and a display having a plurality of subpixels. The plurality of subpixels may include emissive subpixels that emit light and thin-film transistor subpixels that control the emissive subpixels and the display may include a first portion with a first number of emissive subpixels per unit area and a second number of thin-film transistor subpixels per unit area and a second portion with a third number of emissive subpixels per unit area that is equal to the first number and a fourth number of thin-film transistor subpixels per unit area that is less than the second number. The first portion of the display may have emissive subpixels arranged in a checkerboard layout with rows and columns, the second portion of the display may have some emissive subpixels arranged in the checkerboard layout, and the second portion of the display may have some emissive subpixels that are shifted relative to the checkerboard layout.

An electronic device may include an input-output component and a display having a plurality of subpixels. The plurality of subpixels may include emissive subpixels that emit light and thin-film transistor subpixels that control the emissive subpixels. The display may have a portion that overlaps the input-output component. In the portion of the display that overlaps the input-output component, each thin-film transistor subpixel may control at least two respective emissive subpixels, different emissive subpixels of a first color may have different sizes, different emissive subpixels of a second color may have different sizes, and different emissive subpixels of a third color may have a same size.

### BRIEF DESCRIPTION OF THE DRAWINGS

FIG. 1 is a schematic diagram of an illustrative electronic device having a display and one or more sensors in accordance with some embodiments.

FIG. 2 is a schematic diagram of an illustrative display with light-emitting elements in accordance with some embodiments.

FIGS. 3A-3F are top views of illustrative displays showing possible positions for locally modified regions in accordance with some embodiments.

FIG. 4 is a top view of an illustrative normal display region in accordance with some embodiments.

FIG. 5 is a top view of an illustrative locally modified display region with shorted emissive subpixels in accordance with some embodiments.

FIG. 6 is a top view of an illustrative locally modified display region with shorted emissive subpixels of the same color and different sizes in accordance with some embodiments.

FIG. 7 is a top view of an illustrative locally modified display region with groups of four emissive subpixels shorted together and emissive subpixels of the same color and different sizes in accordance with some embodiments.

FIG. 8 is a top view of an illustrative locally modified display region with emissive subpixels that are shifted relative to a checkerboard layout in accordance with some embodiments.

FIG. 9 is a cross-sectional side view of an illustrative display that overlaps an input-output component in accordance with some embodiments.

### DETAILED DESCRIPTION

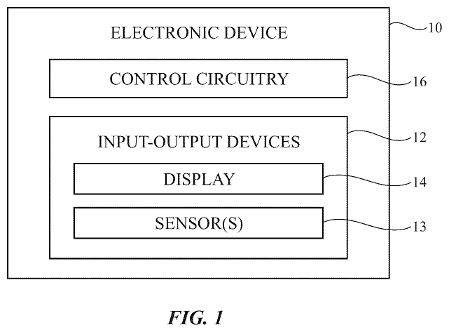

An illustrative electronic device of the type that may be provided with a display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, a device embedded in eyeglasses or other equipment worn on a user's head, or other wearable or miniature device, a display, a computer display that contains an embedded computer, a computer display that does not contain an embedded computer, a gaming device, a navigation device, an embedded system such as a system in which electronic equipment with a display is mounted in a kiosk or automobile, or other electronic equipment. Electronic device 10 may have the shape of a pair of eyeglasses (e.g., supporting frames), may form a housing having a helmet shape, or may have other configurations to help in mounting and securing the components of one or more displays on the head or near the eye of a user.

As shown in FIG. 1, electronic device 10 may include control circuitry 16 for supporting the operation of device 10. Control circuitry 16 may include storage such as hard disk drive storage, nonvolatile memory (e.g., flash memory or other electrically-programmable-read-only memory configured to form a solid-state drive), volatile memory (e.g., static or dynamic random-access memory), etc. Processing circuitry in control circuitry 16 may be used to control the operation of device 10. The processing circuitry may be based on one or more microprocessors, microcontrollers, digital signal processors, baseband processors, power management units, audio chips, application-specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input resources of input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements. A touch sensor for display 14 may be formed from electrodes formed on a common display substrate with the display pixels of display 14 or may be formed from a separate touch sensor panel that overlaps the pixels of display 14. If desired, display 14 may be insensitive to touch (i.e., the touch sensor may be omitted). Display 14 in electronic device 10 may be a head-up display that can be viewed without requiring users to look away from a typical viewpoint or may be a head-mounted display that is incorporated into a device that is worn on a user's head. If desired, display 14 may also be a holographic display used to display holograms.

Control circuitry 16 may be used to run software on device 10 such as operating system code and applications. During operation of device 10, the software running on control circuitry 16 may display images on display 14.

Input-output devices 12 may also include one or more sensors 13 such as force sensors (e.g., strain gauges, capacitive force sensors, resistive force sensors, etc.), audio sensors such as microphones, touch and/or proximity sensors such as capacitive sensors (e.g., a two-dimensional capacitive touch sensor associated with a display and/or a touch sensor that forms a button, trackpad, or other input device not associated with a display), and other sensors. In accordance with some embodiments, sensors 13 may include optical sensors such as optical sensors that emit and detect light (e.g., optical proximity sensors such as transreflective optical proximity structures), ultrasonic sensors, and/or other touch and/or proximity sensors, monochromatic and color ambient light sensors, image sensors, fingerprint sensors, temperature sensors, proximity sensors and other sensors for measuring three-dimensional non-contact gestures (“air gestures”), pressure sensors, sensors for detecting position, orientation, and/or motion (e.g., accelerometers, magnetic sensors such as compass sensors, gyroscopes, and/or inertial measurement units that contain some or all of these sensors), health sensors, radio-frequency sensors, depth sensors (e.g., structured light sensors and/or depth sensors based on stereo imaging devices), optical sensors such as self-mixing sensors and light detection and ranging (lidar) sensors that gather time-of-flight measurements, humidity sensors, moisture sensors, gaze tracking sensors, and/or other sensors. In some arrangements, device 10 may use sensors 13 and/or other input-output devices to gather user input (e.g., buttons may be used to gather button press input, touch sensors overlapping displays can be used for gathering user touch screen input, touch pads may be used in gathering touch input, microphones may be used for gathering audio input, accelerometers may be used in monitoring when a finger contacts an input surface and may therefore be used to gather finger press input, etc.).

Display 14 may be an organic light-emitting diode display, a display formed from an array of discrete light-emitting diodes (microLEDs) each formed from a crystalline semiconductor die, a liquid crystal display or any other suitable type of display. Device configurations in which display 14 is an organic light-emitting diode display are sometimes described herein as an example. This is, however, merely illustrative. Any suitable type of display may be used, if desired. In general, display 14 may have a rectangular shape (i.e., display 14 may have a rectangular footprint and a rectangular peripheral edge that runs around the rectangular footprint) or may have other suitable shapes. Display 14 may be planar or may have a curved profile.

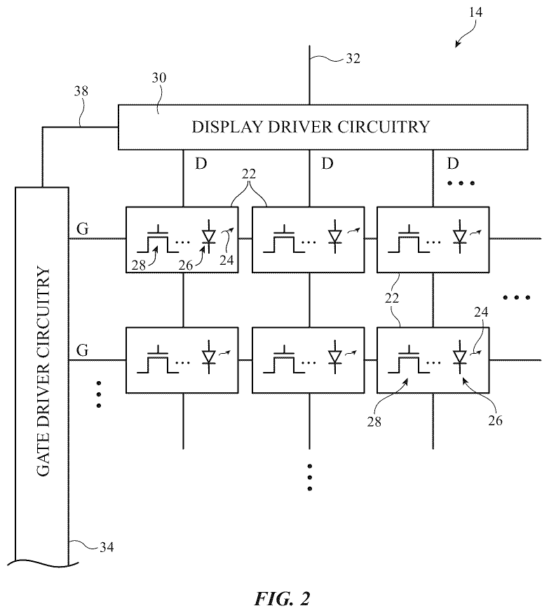

A top view of a portion of display 14 is shown in FIG. 2. As shown in FIG. 2, display 14 may have an array of pixels 22 formed on a substrate. Pixels 22 may receive data signals over signal paths such as data lines D and may receive one or more control signals over control signal paths such as horizontal control lines G (sometimes referred to as gate lines, scan lines, emission control lines, etc.). There may be any suitable number of rows and columns of pixels 22 in display 14 (e.g., tens or more, hundreds or more, or thousands or more). Each pixel 22 may include a light-emitting diode 26 that emits light 24 under the control of a pixel control circuit formed from thin-film transistor circuitry such as thin-film transistors 28 and thin-film capacitors. Thin-film transistors 28 may be polysilicon thin-film transistors, semiconducting-oxide thin-film transistors such as indium zinc gallium oxide (IGZO) transistors, or thin-film transistors formed from other semiconductors. Pixels 22 may contain light-emitting diodes of different colors (e.g., red, green, and blue) to provide display 14 with the ability to display color images or may be monochromatic pixels.

Display driver circuitry may be used to control the operation of pixels 22. The display driver circuitry may be formed from integrated circuits, thin-film transistor circuits, or other suitable circuitry. Display driver circuitry 30 of FIG. 2 may contain communications circuitry for communicating with system control circuitry such as control circuitry 16 of FIG. 1 over path 32. Path 32 may be formed from traces on a flexible printed circuit or other cable. During operation, the control circuitry (e.g., control circuitry 16 of FIG. 1) may supply display driver circuitry 30 with information on images to be displayed on display 14.

To display the images on display pixels 22, display driver circuitry 30 may supply image data to data lines D while issuing clock signals and other control signals to supporting display driver circuitry such as gate driver circuitry 34 over path 38. If desired, display driver circuitry 30 may also supply clock signals and other control signals to gate driver circuitry 34 on an opposing edge of display 14.

Gate driver circuitry 34 (sometimes referred to as row control circuitry) may be implemented as part of an integrated circuit and/or may be implemented using thin-film transistor circuitry. Horizontal control lines G in display 14 may carry gate line signals such as scan line signals, emission enable control signals, and other horizontal control signals for controlling the display pixels 22 of each row. There may be any suitable number of horizontal control signals per row of pixels 22 (e.g., one or more row control signals, two or more row control signals, three or more row control signals, four or more row control signals, etc.).

The region on display 14 where the display pixels 22 are formed may sometimes be referred to herein as the active area. Electronic device 10 has an external housing with a peripheral edge. The region surrounding the active area and within the peripheral edge of device 10 is the border region. Images can only be displayed to a user of the device in the active region. It is generally desirable to minimize the border region of device 10. For example, device 10 may be provided with a full-face display 14 that extends across the entire front face of the device. If desired, display 14 may also wrap around over the edge of the front face so that at least part of the lateral edges or at least part of the back surface of device 10 is used for display purposes.

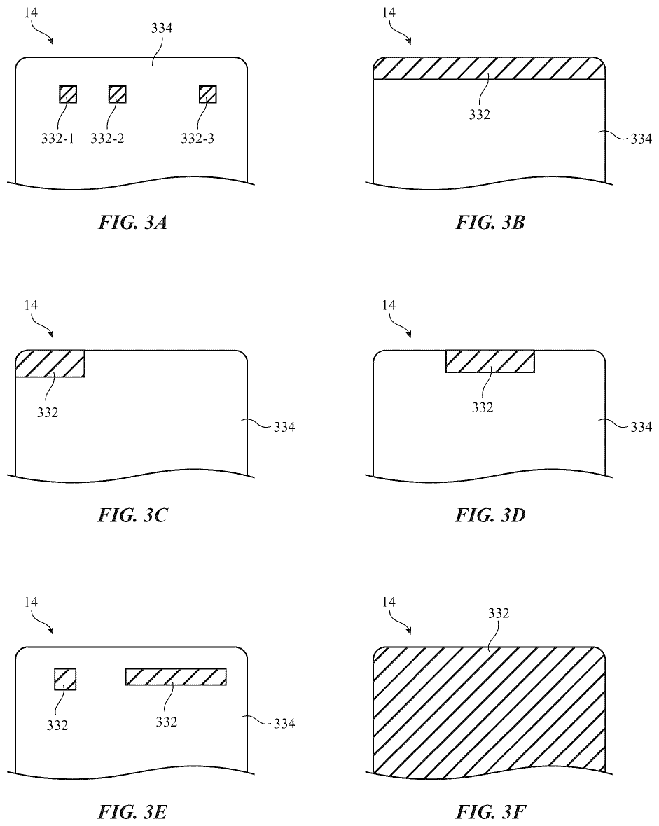

Device 10 may include a sensor 13 mounted behind display 14 (e.g., behind the active area of the display). FIGS. 3A-3F are top views of illustrative displays 14 with a sensor 13 mounted behind the active area (AA) of the display. In some cases, the majority of display 14 may have the same layout. The pixel layout used for the majority of the display may sometimes be referred to as a base layout, majority layout, or normal layout. Portions of display 14 that overlap an input-output component such as sensor 13 may be modified relative to the base layout. In particular, the portions of display 14 that overlap an input-output component may be modified to have a higher transparency than the base layout.

In general, the display may be modified to have an increased transparency in any region(s) of display 14. FIGS. 3A-3F are front views showing how display 14 may have one or more locally modified regions in which the display is modified to increase transparency. The example of FIG. 3A illustrates various locally modified regions 332 physically separated from one another (i.e., the various locally modified regions 332 are non-continuous) by normal display region 334. The locally modified regions 332 may have some modification relative to normal display region 334 that increase transparency. These regions may therefore sometimes be referred to as increased-transparency regions 332, high-transparency regions 332, etc. The normal display region 334 may sometimes be referred to as low-transparency region 334, opaque region 334, etc.

The three locally modified regions 332-1, 332-2, and 332-3 in FIG. 3A might for example correspond to three different sensors formed underneath display 14 (with one sensor per locally modified region). Any portion of the display that is within the field-of-view of an underlying sensor may be modified to increase transparency.

The example of FIG. 3B illustrates a continuous locally modified region 332 formed along the top border of display 14, which might be suitable when there are many optical sensors positioned near the top edge of device 10. The example of FIG. 3C illustrates a locally modified region 332 formed at a corner of display 14 (e.g., a rounded corner area of the display). In some arrangements, the corner of display 14 in which locally modified region 332 is located may be a rounded corner (as in FIG. 3C) or a corner having a substantially 90° corner. The example of FIG. 3D illustrates a locally modified region 332 formed only in the center portion along the top edge of device 10 (i.e., the locally modified region covers a recessed notch area in the display). FIG. 3E illustrates another example in which locally modified regions 332 can have different shapes and sizes. FIG. 3F illustrates yet another suitable example in which the locally modified region covers the entire display surface. In other words, the entire display may have a high transparency as will be later discussed. These examples are merely illustrative and are not intended to limit the scope of the present embodiments. If desired, any one or more portions of the display overlapping with optically based sensors or other sub-display electrical components may be designated as a locally modified region to increase transparency.

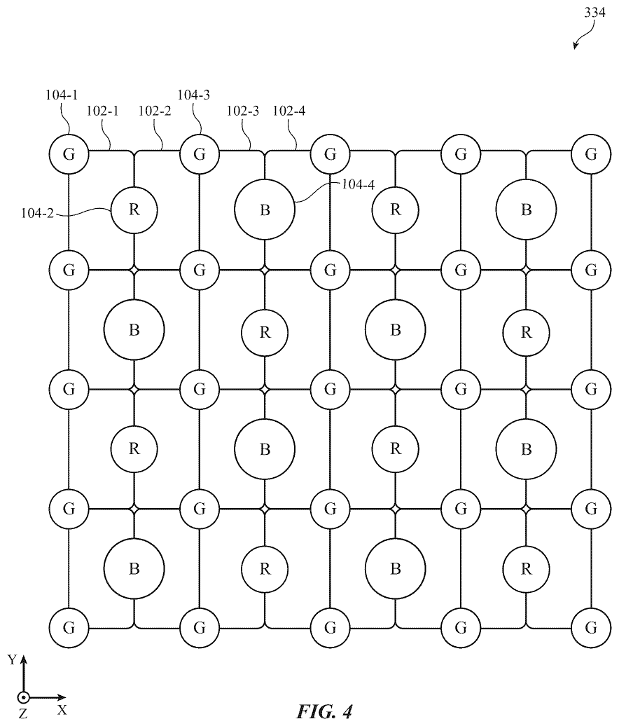

FIG. 4 is a top view of an illustrative normal display region 334. As shown in FIG. 4, in normal display region 334 display 14 includes red subpixels R, blue subpixels B, and green subpixels G. The subpixels are arranged in rows and columns. In the example of FIG. 4, nine columns of subpixel and nine rows of subpixels are shown. In half of the subpixel rows, red and blue subpixels alternate with one column without any subpixels interposed between adjacent subpixels. For example, in the second-from-top row of FIG. 4, the first column has no subpixels, the second column has a red subpixel, the third column has no subpixels, the fourth column has a blue subpixel, the fifth column has no subpixels, etc.

In the remaining half of the rows, green subpixels alternate with one column without any subpixels interposed between adjacent subpixels. For example, in the top row of FIG. 4, the first column has a green subpixel, the second column has no subpixels, the third column has a green subpixel, the fourth column has no subpixels, the fifth column has a green subpixel, etc.

In other words, in the normal display region the subpixels have a checkerboard pattern that is arranged in a regular grid of rows and columns. The rows extend in the X-direction and the columns extend in the Y-direction. This pattern may be referred to as a checkerboard layout.

FIG. 4 shows a layout for subpixels R, G, and B in normal display region 334. It should be noted that these layouts are for the emissive layer of each subpixel. Each display pixel 22 may include both a thin-film transistor layer and an emissive layer. Each emissive layer portion may have associated circuitry on the thin-film transistor layer that controls the magnitude of light emitted from that emissive layer portion. Both the emissive layer and thin-film transistor layer may have corresponding subpixels within the pixel. Each subpixel may be associated with a different color of light (e.g., red, green, and blue). The emissive layer portion for a given subpixel does not necessarily need to have the same footprint as its associated thin-film transistor layer portion. Hereinafter, the term subpixel may sometimes be used to refer to the combination of an emissive layer portion and a thin-film transistor layer portion. Additionally, the thin-film transistor layer may be referred to as having thin-film transistor subpixels (e.g., a portion of the thin-film transistor layer that controls a respective emissive area, sometimes referred to as thin-film transistor layer pixels, thin-film transistor layer subpixels or simply subpixels) and the emissive layer may be referred to as having emissive layer subpixels (sometimes referred to as emissive pixels, emissive subpixels or simply subpixels).

Subpixels R, G, and B in FIG. 4 are therefore emissive subpixels. FIG. 4 also shows a layout for thin-film transistor subpixels 102. As shown in FIG. 4, normal display region 334 may include thin-film transistor subpixels 102 arranged in a regular grid of rows and columns. A first thin-film transistor subpixel 102-1 may control the emission of light from a respective emissive subpixel 104-1, a second thin-film transistor subpixel 102-2 may control the emission of light from a respective emissive subpixel 104-2, a third thin-film transistor subpixel 102-3 may control the emission of light from a respective emissive subpixel 104-3, a fourth thin-film transistor subpixel 102-4 may control the emission of light from a respective emissive subpixel 104-4, etc.

In order to increase the transmission of light through locally modified region 332 without reducing the apparent pixel density of the display in locally modified region 332, one or more thin-film transistor subpixels 102 may be removed from locally modified region 332 relative to normal region 334. For example, each thin-film transistor subpixel 102 may control the light emitted from two emissive subpixels (e.g., that are shorted together). This reduces the number of thin-film transistor subpixels by 50% relative to the normal display region of FIG. 4.

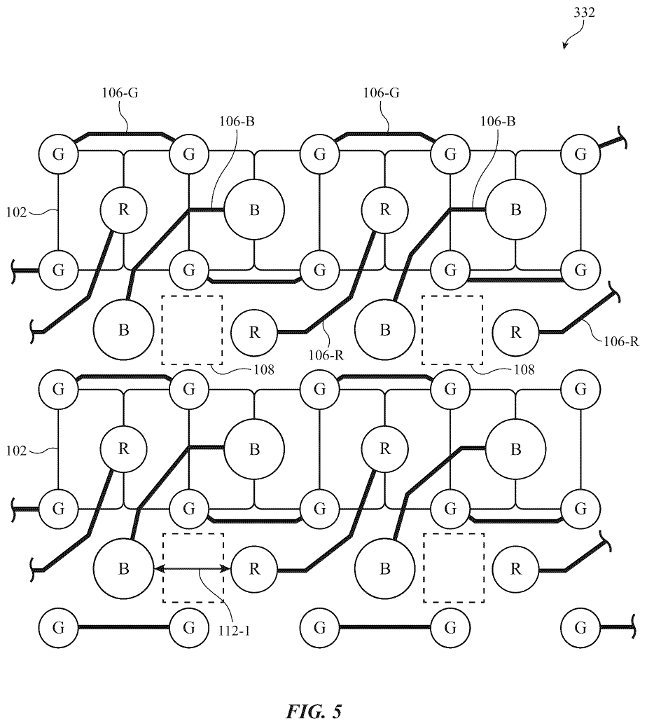

FIG. 5 is a top view of a pixel removal region where each thin-film transistor subpixel controls two respective emissive subpixels. As shown in FIG. 5, the emissive subpixels in modified display region 332 have the same layout as in normal display region 334. However, every other row of thin-film transistor subpixels is omitted in modified display region 332 relative to normal display region 334. Omitting every other row of thin-film transistor subpixels creates transmissive areas 108 between emissive subpixels. The transmissive areas 108 (sometimes referred to as transparent openings 108, windows 108, high transmission areas 108, pixel-free areas, transparent windows 108, etc.) may allow for light to be transmitted through the display to an underlying sensor or for light to be transmitted through the display from a light source underneath the display. The transparency of transparent areas 108 (for visible and/or infrared light) may be greater than 25%, greater than 30%, greater than 40%, greater than 50%, greater than 60%, greater than 70%, greater than 80%, greater than 90%, etc.

To maintain the same number of emissive subpixels per unit area in modified region 332 as in normal region 334 while omitting at least 50% of the thin-film transistor subpixels in modified region 332 relative to normal region 334, each thin-film transistor subpixel in modified region 332 may control at least two respective emissive subpixels. As shown in FIG. 5, each adjacent pair of green emissive subpixels may be shorted together by a respective shorting path 106-G, each adjacent pair of blue emissive subpixels may be shorted together by a respective shorting path 106-B, and each adjacent pair of red emissive subpixels may be shorted together by a respective shorting path 106-R.

Shorting paths 106 may be formed by conductive routing lines on one or more layers within the display (e.g., within the thin-film transistor circuitry layer in the display). Each shorting path may electrically connect the first anode of a first emissive subpixel to the second anode of a second emissive subpixel. In this way, when a thin-film transistor subpixel applies a drive voltage to the first anode, the drive voltage is also applied to the second anode. Both the first and second emissive subpixels therefore emit approximately the same amount of light. This partially reduces the effective resolution of the display in locally modified region 332 (since the shorted pixels necessarily emit the same amount of light). However, the display may still have a satisfactory appearance to the viewer in locally modified region 332 even with the shorted emissive subpixels.

In total, locally modified region 332 in FIG. 5 has 100% of the emissive subpixels per unit area as normal display region 334 and 50% of the thin-film transistor subpixels per unit area relative to the normal display region 334.

The performance of a sensor overlapped by locally modified region 332 may improve with increasing size of transmissive windows 108. The greater the number and size of transmissive windows 108, the greater the overall open ratio will be for locally modified region 332. To increase the size of transmissive windows 108, emissive subpixels of the same color may have different sizes within locally modified region 332.

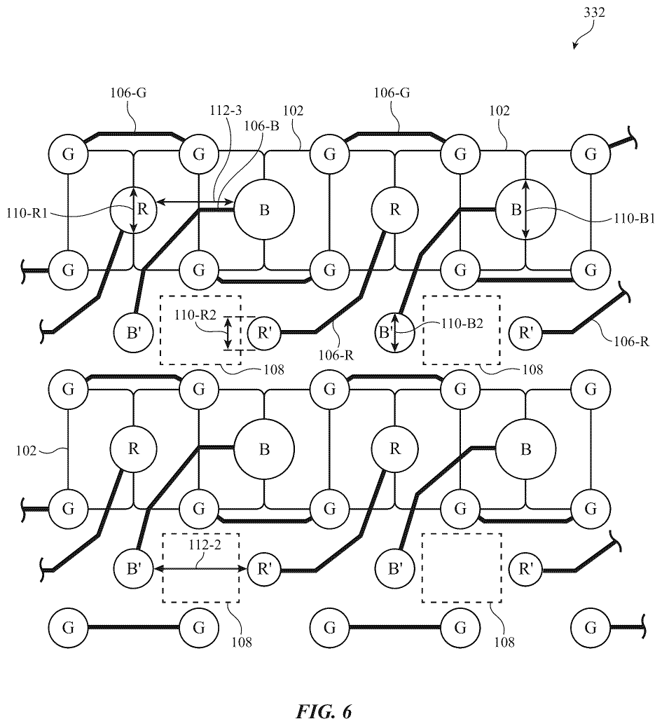

FIG. 6 is a top view of a locally modified region 332 with emissive subpixels of the same color and different sizes. As shown in FIG. 6, each adjacent pair of green emissive subpixels may be shorted together by a respective shorting path 106-G, each adjacent pair of blue emissive subpixels may be shorted together by a respective shorting path 106-B, and each adjacent pair of red emissive subpixels may be shorted together by a respective shorting path 106-R (similar to as in FIG. 5). However, the shorted pairs of blue emissive subpixels have different sizes (areas) and the shorted pairs of red emissive subpixels have different sizes (areas). In the example of FIG. 6, the red subpixels shorted together have different sizes and the blue subpixels shorted together have different sizes.

A first subset of the blue emissive subpixels (marked as B in FIG. 6) has a first diameter 110-B1. A second subset of the blue emissive subpixels (marked as B′ in FIG. 6) has a second diameter 110-B2 that is smaller than the first diameter. In other words, the blue emissive subpixels B that overlap the thin-film transistor subpixels 102 have a larger area than the blue emissive subpixels B′ that do not overlap the thin-film transistor subpixels 102. It is noted that each blue emissive subpixel in the normal display region 334 has an area that is greater than the area of each subpixel B′ in region 332 but less than the area of each subpixel B in region 332. Similarly, it is noted that each blue emissive subpixel in the normal display region 334 has a diameter that is greater than the diameter of each subpixel B′ in region 332 but less than the diameter of each subpixel B in region 332.

A first subset of the red emissive subpixels (marked as R in FIG. 6) has a first diameter 110-R1. A second subset of the red emissive subpixels (marked as R′ in FIG. 6) has a second diameter 110-R2 that is smaller than the first diameter. In other words, the red emissive subpixels R that overlap the thin-film transistor subpixels 102 have a larger area than the red emissive subpixels R′ that do not overlap the thin-film transistor subpixels 102. It is noted that each red emissive subpixel in the normal display region 334 has an area that is greater than the area of each subpixel R′ in region 332 but less than the area of each subpixel R in region 332. Similarly, it is noted that each red emissive subpixel in the normal display region 334 has a diameter that is greater than the diameter of each subpixel R′ in region 332 but less than the diameter of each subpixel R in region 332.

With the arrangement of FIG. 6, each red emissive subpixel R has a total area that is greater than the total area of each red emissive subpixel R′ by at least 10%, at least 20%, at least 50%, at least 100%, at least 150%, at least 200%, etc. Each blue emissive subpixel B has a total area that is greater than the total area of each blue emissive subpixel B′ by at least 10%, at least 20%, at least 50%, at least 100%, at least 150%, at least 200%, etc. Diameter 110-R1 may be greater than diameter 110-R2 by at least 5%, at least 10%, at least 20%, at least 50%, at least 100%, etc. Diameter 110-B1 may be greater than diameter 110-B2 by at least 5%, at least 10%, at least 20%, at least 50%, at least 100%, etc.

The example herein of the emissive subpixels having circular footprints is merely illustrative. The emissive subpixels may have any desired footprint shapes (e.g., square, non-square rectangular, oval, etc.). Each red emissive subpixel R may have a length that is greater than the length of each red emissive subpixel R′ by at least 5%, at least 10%, at least 20%, at least 50%, at least 100%, etc. Each red emissive subpixel R may have a width that is greater than the width of each red emissive subpixel R′ by at least 5%, at least 10%, at least 20%, at least 50%, at least 100%, etc. Each blue emissive subpixel B may have a length that is greater than the length of each blue emissive subpixel B′ by at least 5%, at least 10%, at least 20%, at least 50%, at least 100%, etc. Each blue emissive subpixel B may have a width that is greater than the width of each blue emissive subpixel B′ by at least 5%, at least 10%, at least 20%, at least 50%, at least 100%, etc.

In FIG. 6, the emissive subpixels are arranged in a checkerboard pattern similar to as in FIGS. 4 and 5. However, in FIG. 5 each pair of adjacent blue and red subpixels within each row are separated by a distance 112-1. In FIG. 6, in a first half of the rows of blue and red subpixels (with subpixels R′ and B′), each pair of adjacent blue and red subpixels within each row are separated by a distance 112-2 and in a second half of the rows of blue and red subpixels (with subpixels R and B), each pair of adjacent blue and red subpixels within each row are separated by a distance 112-3. Distance 112-1 is greater than distance 112-3. Distance 112-1 is less than distance 112-2. The gap between emissive subpixels is therefore greater in an area of region 332 that does not overlap thin-film transistor subpixels 102 than in an area of region 332 that does overlap thin-film transistor subpixels. This increases the size of transparent windows 108 in region 332.

In total, locally modified region 332 in FIG. 6 has 100% of the emissive subpixels per unit area as normal display region 334 and 50% of the thin-film transistor subpixels per unit area relative to the normal display region 334 (similar to as in FIG. 5). However, the blue and red subpixels have varying sizes in the modified region 332 of FIG. 6.

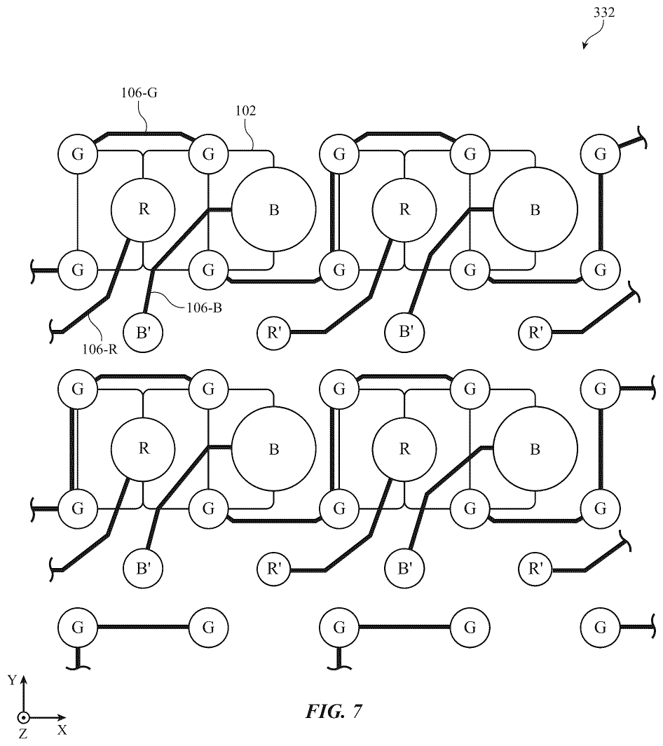

In FIGS. 5 and 6, each thin-film transistor subpixel controls two emissive subpixels. This example is merely illustrative. In another possible arrangement, shown in FIG. 7, a first subset of the thin-film transistor subpixels controls two emissive subpixels and a second subset of the thin-film transistor subpixels controls four emissive subpixels. As shown in FIG. 7, two blue emissive subpixels may be shorted together by a respective shorting path 106-B and controlled by a single respective thin-film transistor subpixel and two red emissive subpixels may be shorted together by a respective shorting path 106-R and controlled by a single respective thin-film transistor subpixel (similar to as in FIGS. 5 and 6). However, in FIG. 7, four green emissive subpixels may be shorted together by a respective shorting path 106-G and controlled by a single respective thin-film transistor subpixel. Shorting together four green emissive subpixels per thin-film transistor subpixel (as in FIG. 7) instead of two green emissive subpixels per thin-film transistor subpixel (as in FIG. 6) allows for additional thin-film transistor subpixels to be omitted in FIG. 7 relative to FIG. 6.

In total, locally modified region 332 in FIG. 7 has 100% of the emissive subpixels per unit area as normal display region 334 and 37.5% of the thin-film transistor subpixels per unit area relative to the normal display region 334. The blue and red subpixels in FIG. 7 also have varying sizes in the modified region 332 (similar to as previously shown and discussed in connection with FIG. 6).

The number of thin-film transistor subpixels per unit area in modified region 332 may be less than or equal to 50% of the number of thin-film transistor subpixels per unit area in normal region 334.

To further increase the size of each transparent window 108, one or more of the emissive subpixels in locally modified region 332 may be shifted relative to their corresponding location in normal display region 334. In FIGS. 4-7, the emissive subpixels are arranged in a checkerboard pattern. The centers of the emissive subpixels are aligned in parallel columns (which extend in the Y-direction) and parallel rows (which extend in the X-direction). In FIGS. 6 and 7, although the sizes of the emissive subpixels are changed relative to FIGS. 4 and 5, the alignment of the centers of the emissive subpixels in the checkerboard pattern is unchanged.

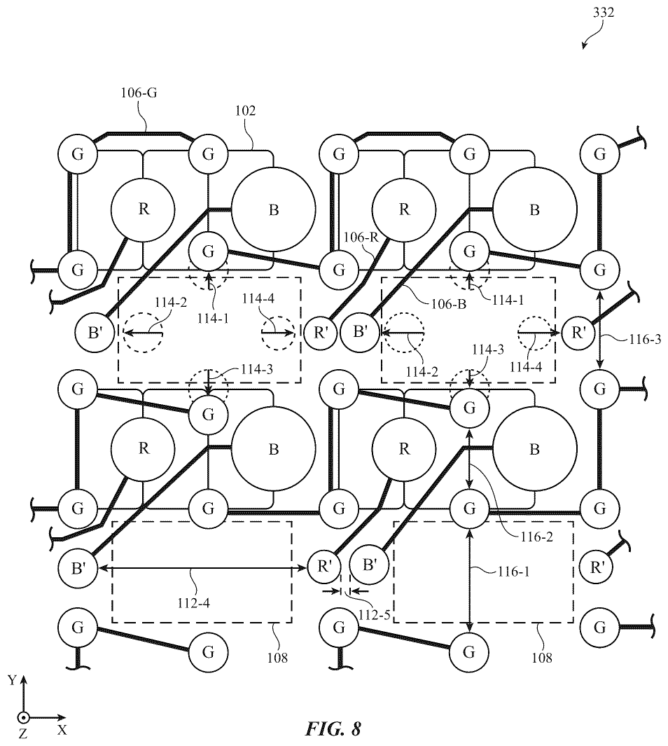

In FIG. 8, locally modified region 332 has emissive subpixels with centers that are shifted from the checkerboard pattern of FIGS. 4-7. As shown, a subset of the emissive subpixels may be shifted in the positive Y-direction (as indicated by arrow 114-1) relative to the checkerboard grid position (shown by the dashed outline) for that emissive subpixel. A subset of the emissive subpixels may be shifted in the negative X-direction (as indicated by arrow 114-2) relative to the checkerboard grid position (shown by the dashed outline) for that emissive subpixel. A subset of the emissive subpixels may be shifted in the negative Y-direction (as indicated by arrow 114-3) relative to the checkerboard grid position (shown by the dashed outline) for that emissive subpixel. A subset of the emissive subpixels may be shifted in the positive X-direction (as indicated by arrow 114-4) relative to the checkerboard grid position (shown by the dashed outline) for that emissive subpixel.

Shifting the emissive subpixels as shown in FIG. 8 increases the size of each transparent window 108. With the arrangement of FIG. 8, within a given row of red and blue subpixels that is not overlapped by the thin-film transistor subpixels, a first pair of adjacent red and blue subpixels is separated by a distance 112-4 whereas a second pair of adjacent red and blue subpixels is separated by a distance 112-5. Distance 112-4 is greater than distance 112-5 (e.g., by at least 20%, by at least 50%, by at least 100%, by at least 200%, by at least 300%, etc.). Distance 112-4 is greater than distance 112-2 in FIG. 6 whereas distance 112-5 is less than distance 112-2 in FIG. 6.

With the arrangement of FIG. 8, within a given column of green subpixels, a first pair of adjacent green emissive subpixels is separated by a distance 116-1 whereas a second pair of adjacent green emissive subpixels is separated by a distance 116-2. Distance 116-1 is greater than distance 116-2 (e.g., by at least 20%, by at least 50%, by at least 100%, by at least 200%, by at least 300%, etc.). A first half of the columns of green emissive subpixels may have shifted green emissive subpixels as indicated by varying distances 116-1 and 116-2 in FIG. 8. However, a second half of the columns of green emissive subpixels may have a uniform separation distance 116-3 between adjacent green emissive subpixels.

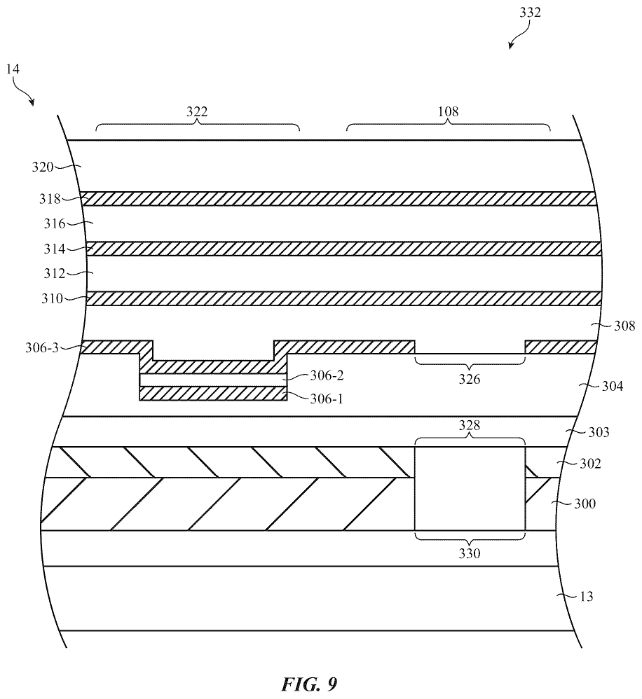

FIG. 9 is a cross-sectional side view of an illustrative display stack of display 14 that at least partially covers a sensor in accordance with an embodiment. As shown in FIG. 9, the display stack may include a substrate such as substrate 300. Substrate 300 may be formed from glass, metal, plastic, ceramic, sapphire, or other suitable substrate materials. In some arrangements, substrate 300 may be an organic substrate formed from polyethylene terephthalate (PET) or polyethylene naphthalate (PEN) (as examples). One or more polyimide (PI) layers 302 may be formed over substrate 300. The polyimide layers may sometimes be referred to as an organic substrate (e.g., substrate 300 is a first substrate layer and substrate 302 is a second substrate layer). The surface of substrate 302 may optionally be covered with one or more buffer layers 303 (e.g., inorganic buffer layers such as layers of silicon oxide, silicon nitride, amorphous silicon, etc.).

Thin-film transistor (TFT) layers 304 may be formed over inorganic buffer layers 303 and organic substrates 302 and 300. The TFT layers 304 may include thin-film transistor circuitry such as thin-film transistors, thin-film capacitors, associated routing circuitry, and other thin-film structures formed within multiple metal routing layers and dielectric layers. Organic light-emitting diode (OLED) layers 306 may be formed over the TFT layers 304. The OLED layers 306 may include a diode cathode layer, a diode anode layer, and emissive material interposed between the cathode and anode layers. The OLED layers may include a pixel definition layer that defines the light-emitting area of each pixel. The TFT circuitry in layer 304 may be used to control an array of display pixels formed by the OLED layers 306.

Circuitry formed in the TFT layers 304 and the OLED layers 306 may be protected by encapsulation layers 308. As an example, encapsulation layers 308 may include a first inorganic encapsulation layer, an organic encapsulation layer formed on the first inorganic encapsulation layer, and a second inorganic encapsulation layer formed on the organic encapsulation layer. Encapsulation layers 308 formed in this way can help prevent moisture and other potential contaminants from damaging the conductive circuitry that is covered by layers 308. Substrate 300, polyimide layers 302, buffer layers 303, TFT layers 304, OLED layers 306, and encapsulation layers 308 may be collectively referred to as a display panel.

One or more polarizer films 312 may be formed over the encapsulation layers 308 using adhesive 310. Adhesive 310 may be implemented using optically clear adhesive (OCA) material that offers high light transmittance. One or more touch layers 316 that implement the touch sensor functions of touch-screen display 14 may be formed over polarizer films 312 using adhesive 314 (e.g., OCA material). For example, touch layers 316 may include horizontal touch sensor electrodes and vertical touch sensor electrodes collectively forming an array of capacitive touch sensor electrodes. Lastly, the display stack may be topped off with a cover glass layer 320 (sometimes referred to as a display cover layer 320) that is formed over the touch layers 316 using additional adhesive 318 (e.g., OCA material). display cover layer 320 may be a transparent layer (e.g., transparent plastic or glass) that serves as an outer protective layer for display 14. The outer surface of display cover layer 320 may form an exterior surface of the display and the electronic device that includes the display.

Still referring to FIG. 9, sensor 13 may be formed under the display stack within the electronic device 10. As described above in connection with FIG. 1, sensor 13 may be an optical sensor such as a camera, proximity sensor, ambient light sensor, fingerprint sensor, or other light-based sensor. In some cases, sensor 13 may include a light-emitting component that emits light through the display. Sensor 13 may therefore sometimes be referred to as input-output component 13. Input-output component 13 may be a sensor or a light-emitting component (e.g., that is part of a sensor).

FIG. 9 shows a high-transmittance area 108 in addition to a pixel region 322. At least some of the display stack may be selectively removed in high-transmittance area 108 located directly over sensor(s) 13. Removing thin-film transistor subpixel(s) in transparent window 108 may help increase transmission and improve the performance of the under-display sensor 13. In addition to removing thin-film transistor subpixels, portions of additional layers such as polyimide layers 302 and/or substrate 300 may be removed for additional transmission improvement. Polarizer 312 may also be bleached for additional transmission improvement.

In the pixel region 322, the display may include a pixel formed from emissive material 306-2 that is interposed between an anode 306-1 and a cathode 306-3. Signals may be selectively applied to anode 306-1 to cause emissive material 306-2 to emit light for the pixel. Circuitry in thin-film transistor layer 304 may be used to control the signals applied to anode 306-1. In high-transmittance area 108, anode 306-1 and emissive material 306-2 (and any associated thin-film transistor subpixel) may be omitted. Additional circuitry within thin-film transistor layer 304 may also be omitted in high-transmittance area 324 to increase transmittance.

Additional transmission improvements through the display stack may be obtained by selectively removing additional components from the display stack in high-transmittance area 108. As shown in FIG. 9, a portion of cathode 306-3 may be removed in high-transmittance area 108. This results in an opening 326 in the cathode 306-3. Said another way, the cathode 306-3 may have conductive material that defines an opening 326 in the high-transmittance area. Removing the cathode in this way allows for more light to pass through the display stack to sensor 13. Cathode 306-3 may be formed from any desired conductive material. The cathode may be removed via etching (e.g., laser etching or plasma etching). Alternatively, the cathode may be patterned to have an opening in high-transmittance area 108 during the original cathode deposition and formation steps.

Polyimide layers 302 may be removed in high-transmittance area 108 in addition to cathode layer 306-3. The removal of the polyimide layers 302 results in an opening 328 in the high-transmittance area 108. Said another way, the polyimide layer may have polyimide material that defines an opening 328 in the high-transmittance region. The polyimide layers may be removed via etching (e.g., laser etching or plasma etching). Alternatively, the polyimide layers may be patterned to have an opening in high-transmittance area 108 during the original polyimide formation steps. Removing the polyimide layer 302 in high-transmittance area 108 may result in additional transmittance of light to sensor 13 in high-transmittance area 108.

Substrate 300 may be removed in high-transmittance area 108 in addition to cathode layer 306-3 and polyimide layer 302. The removal of the substrate 300 results in an opening 330 in the high-transmittance area. Said another way, the substrate 300 may have material (e.g., PET, PEN, etc.) that defines an opening 330 in the high-transmittance area. The substrate may be removed via etching (e.g., with a laser). Alternatively, the substrate may be patterned to have an opening in high-transmittance area 108 during the original substrate formation steps. Removing the substrate 300 in high-transmittance area 108 may result in additional transmittance of light in high-transmittance area 108. The polyimide opening 328 and substrate opening 330 may be considered to form a single unitary opening. When removing portions of polyimide layer 302 and/or substrate 300, inorganic buffer layers 303 may serve as an etch stop for the etching step. Openings 328 and 330 may be filled with air or another desired transparent filler.

In addition to having openings in cathode 306-3, polyimide layers 302, and/or substrate 300, the polarizer 312 in the display may be bleached for additional transmittance in the pixel removal region.

The foregoing is merely illustrative and various modifications can be made by those skilled in the art without departing from the scope and spirit of the described embodiments. The foregoing embodiments may be implemented individually or in any combination.

What is claimed is:

1. An electronic device, comprising:
an input-output component; and
a display having a plurality of subpixels, wherein the plurality of subpixels comprises emissive subpixels that emit light and thin-film transistor subpixels that control the emissive subpixels and wherein the display comprises:
a first portion with a first number of emissive subpixels per unit area and a second number of thin-film transistor subpixels per unit area, wherein, in the first portion, each emissive subpixel of a first color has a first area; and
a second portion with a third number of emissive subpixels per unit area that is equal to the first number and a fourth number of thin-film transistor subpixels per unit area that is less than the second number, wherein the second portion overlaps the input-output component and wherein, in the second portion, a first subset of emissive subpixels of the first color each has a second area that is larger than the first area and a second subset of emissive subpixels of the first color each has a third area that is smaller than the first area.

2. The electronic device defined in claim 1, wherein each one of the first subset of emissive subpixels of the first color in the second display portion overlaps at least one respective thin-film transistor subpixel.

3. The electronic device defined in claim 2, wherein each one of the second subset of emissive subpixels of the first color in the second display portion does not overlap any of the thin-film transistor subpixels.

4. The electronic device defined in claim 1, wherein the fourth number of thin-film transistor subpixels per unit area is less than or equal to 50% of the second number.

5. The electronic device defined in claim 1, wherein the fourth number of thin-film transistor subpixels per unit area is 50% of the second number.

6. The electronic device defined in claim 1, wherein the fourth number of thin-film transistor subpixels per unit area is 37.5% of the second number.

7. The electronic device defined in claim 1, wherein, in the first portion, each emissive subpixel of a second color has a fourth area and wherein, in the second portion, a third subset of emissive subpixels of the second color each has a fifth area that is larger than the fourth area and a fourth subset of emissive subpixels of the second color each has a sixth area that is smaller than the fourth area.

8. The electronic device defined in claim 7, wherein, in the first portion, each emissive subpixel of a third color has a seventh area and wherein, in the second portion, each emissive subpixel of the third color has the seventh area.

9. The electronic device defined in claim 8, wherein the first color is red, the second color is blue, and the third color is green.

10. The electronic device defined in claim 1, wherein, in the first portion of the display, each thin-film transistor subpixel controls only a single emissive subpixel.

11. The electronic device defined in claim 10, wherein, in the second portion of the display, each thin-film transistor subpixel controls two emissive subpixels.

12. The electronic device defined in claim 10, wherein, in the second portion of the display, some of the thin-film transistor subpixels control two emissive subpixels and some of the thin-film transistor subpixels control four emissive subpixels.

13. The electronic device defined in claim 1, wherein, in the second portion of the display, pairs of red emissive subpixels are shorted together, pairs of blue emissive subpixels are shorted together, and pairs of green emissive subpixels are shorted together.

14. The electronic device defined in claim 1, wherein, in the second portion of the display, pairs of red emissive subpixels are shorted together, pairs of blue emissive subpixels are shorted together, and groups of four green emissive subpixels are shorted together.

15. The electronic device defined in claim 1, wherein the first portion of the display has emissive subpixels arranged in a checkerboard layout, wherein the second portion of the display has some emissive subpixels arranged in the checkerboard layout, and wherein the second portion of the display has some emissive subpixels that are shifted relative to the checkerboard layout.

16. The electronic device defined in claim 15, wherein the emissive subpixels in the second portion of the display that are shifted relative to the checkerboard layout comprise a first emissive subpixel that is shifted in a first direction relative to the checkerboard layout, a second emissive subpixel that is shifted in a second direction that is orthogonal to the first direction relative to the checkerboard layout, a third emissive subpixel that is shifted in a third direction that is opposite the first direction relative to the checkerboard layout, and a fourth emissive subpixel that is shifted in a fourth direction that is opposite the second direction relative to the checkerboard layout.

17. The electronic device defined in claim 16, wherein the display comprises a transparent window that is interposed between the first, second, third, and fourth emissive subpixels.

18. An electronic device, comprising:
an input-output component; and
a display having a plurality of subpixels, wherein the plurality of subpixels comprises emissive subpixels that emit light and thin-film transistor subpixels that control the emissive subpixels and wherein the display comprises:
a first portion with a first number of emissive subpixels per unit area and a second number of thin-film transistor subpixels per unit area, wherein the first portion of the display has emissive subpixels arranged in a checkerboard layout with rows and columns; and
a second portion with a third number of emissive subpixels per unit area that is equal to the first number and a fourth number of thin-film transistor subpixels per unit area that is less than the second number, wherein the second portion of the display has some emissive subpixels arranged in the checkerboard layout and wherein the second portion of the display has some emissive subpixels that are shifted relative to the checkerboard layout.

19. The electronic device defined in claim 18, wherein the emissive subpixels in the first portion of the display overlap the thin-film transistor subpixels, wherein the emissive subpixels in the second portion of the display that are arranged in the checkerboard layout overlap the thin-film transistor subpixels, and wherein the emissive subpixels in the second portion of the display that are shifted relative to the checkerboard layout do not overlap any of the thin-film transistor subpixels.

20. An electronic device, comprising:
an input-output component; and
a display having a plurality of subpixels, wherein the plurality of subpixels comprises emissive subpixels that emit light and thin-film transistor subpixels that control the emissive subpixels, wherein the display has a portion that overlaps the input-output component, and wherein, in the portion of the display that overlaps the input-output component:
each thin-film transistor subpixel controls at least two respective emissive subpixels;
different emissive subpixels of a first color have different sizes;
different emissive subpixels of a second color have different sizes; and
different emissive subpixels of a third color have a same size.
